(19) United States
(12) Patent Application Publication
(10) Pub. No.: US 2008/0283930 A1
(43) Pub. Date: Nov. 20, 2008

(54) EXTENDED DEPTH INTER-WELL ISOLATION STRUCTURE

(75) Inventors: Thomas W. Dyer, Pleasant Valley, NY (US); Haining S. Yang, Wappingers Falls, NY (US)

Correspondence Address: SCULLY, SCOTT, MURPHY & PRESSER, P.C., 400 GARDEN CITY PLAZA, Suite 300, GARDEN CITY, NY, 11530, US

(73) Assignee: INTERNATIONAL BUSINESS MACHINES CORPORATION, Armonk, NY (US)

(21) Appl. No.: 11/748,528

(22) Filed: May 15, 2007

(51) Int. Cl. H01L 21/8238; H01L 29/76

(52) U.S. Cl. 257/371; 438/227; 257/E29.226; 257/E21.632

(57) ABSTRACT

By depositing and forming a spacer out of a semiconductor material layer or a dielectric material layer on the edges of an inter-well isolation area while forming a plug over an intra-well isolation area, a narrow intra-well isolation trench having a normal depth is formed in the intra-well isolation area, while a wider inter-well isolation trench having an extended portion is formed in the inter-well isolation area. The extended portion of the inter-well isolation trench provides enhanced inter-well isolation due to the presence of the extended portion beneath the normal depth. The extended portion of the inter-well isolation trench enables reduction of the width of the intra-well isolation trench structure relative to prior art inter-well isolation structures having a normal depth.

### FIELD OF THE INVENTION

The present invention relates to a semiconductor structure, and particularly to an intra-well isolation structure with an extended depth and methods of manufacturing the same.

### BACKGROUND OF THE INVENTION

A typical semiconductor device in a complementary metal-oxide-semiconductor (CMOS) circuit is formed in a p-well or an n-well in a semiconductor substrate. Since other semiconductor devices are also present in the semiconductor substrate, the semiconductor device requires electrical isolation from adjacent semiconductor devices. Electrical isolation is provided by isolation structures that employ trenches filled with an insulator material. Electrical isolation of the semiconductor device from other devices located in the same well is called “intra-well isolation.” Electrical isolation of the semiconductor device from other devices in an adjacent well of the opposite type is called “inter-well isolation.” In both cases, unintended functionality of parasitic devices, such as parasitic pnp or npn bipolar transistors, formed by various elements of the semiconductor device and adjacent semiconductor devices, needs to be suppressed by placing dielectric material, typically in the form of trench isolation structures, in the current paths among the elements of the parasitic devices.

Referring to FIG. 1, a vertical cross-sectional view of a prior art trench isolation structure having minimum separation distances between adjacent device regions shows an inter-well trench isolation structure 4, and two intra-well trench isolation structures 6. One of the intra-well trench isolation structure 6 is located within a p-well 11, while the other is located within an n-well 12. The inter-well isolation structure 4 is located at a boundary between the p-well 11 and the n-well 12. Both the p-well 11 and the n-well 12 are located above a substrate layer 10′, which typically has the same doping level as the original semiconductor substrate prior to the doping of the wells (11, 12). Typically, at least one heavily n-doped region 91, such as source and drain regions of an n-type field effect transistor, is located above the p-well 11, and at least one heavily p-doped region 92, such as source and drain regions of a p-type field effect transistor, is located above the n-well 12. The at least one heavily n-doped region 91, the at least one heavily p-doped region 92, the p-well 11, the n-well 12, the two intra-well trench isolation structures 6, the inter-well trench isolation structure 4, and the substrate layer 10′ are located within a semiconductor substrate 8.

Typically, the depths of the inter-well trench isolation structure 4 and the intra-well trench isolation structures 6 are substantially the same. Variations between the various depths of the trench isolation structures (4, 6), that is, variations in the heights of inter-well trench sidewalls 66 and intra-well trench sidewalls 61, are typically caused by process bias between trenches having different widths during a reactive ion etch of the trenches. Therefore, the inter-well trench bottom surface 67 and the intra-well trench bottom surface 62 are substantially at the same depth from a top surface of the semiconductor substrate 8.

An inter-well trench minimum width w1_p of the inter-well trench isolation structure 4 is determined by a combination of the depth of the inter-well trench isolation structure 4 (which is the same as the height of the inter-well trench isolation sidewalls 66), the depths of the at least one heavily n-doped region 91 and the at least one heavily p-doped region 92, the doping levels of the p-well 11 and the n-well 12, the overlay tolerances of lithography processes that are used to form the two wells (11, 12), and the operating voltages of the semiconductor devices abutting the inter-well trench isolation structure 4. An intra-well trench minimum width w2_p of the intra-well trench isolation structure 6 is determined by a combination of the depth of the intra-well trench isolation structure 6, the depth of the at least one heavily n-doped region 91 or the at least one heavily n-doped region 92, the doping level of the p-well 11 or the n-well 12, and the operating voltages of the semiconductor devices abutting the intra-well trench isolation structure 6.

The paths of the weakest inter-well isolation in the prior art isolation structure are represented by a prior art heavily n-doped region to n-well separation distance d₂ₚ_{_{—}}ₚ and a prior art heavily p-doped region to p-well separation distance d₂ₙ_{_{—}}ₚ in FIG. 1. Likewise, the path of the weakest intra-p-well isolation in the prior art isolation structure is represented by a prior art heavily n-doped region to another heavily n-doped region separation distance d₁ₚ_{_{—}}ₚ. The path of the weakest intra-n-well isolation in the prior art isolation structure is represented by a prior art heavily p-doped region to another heavily p-doped region separation distance d₁ₙ_{_{—}}ₚ. From geometrical considerations, the inter-well trench minimum width w1_p needs to be greater than the intra-well trench minimum width w2_p due to the presence of the boundary between the p-well 11 and the n-well 12 near the middle of the inter-well trench isolation structure 4.

For example, the depths of the at least one heavily n-doped region 91 and the at least one heavily p-doped region 92 may be about 80 nm, the depths of the various trench isolation structures (4, 6) may be about 280 nm, and the overlay tolerance of lithography processes for ion implantations well definition may be about 30 nm. For 1. V operation of semiconductor devices, this requires the inter-well trench minimum width w1_p to be about 208 nm such that each of the prior art heavily n-doped region to n-well separation distance d₂ₚ_{_{—}}ₚ and the prior art heavily p-doped region to p-well separation distance d₂ₙ_{_{—}}ₚ is at least 289 nm. The prior art heavily n-doped region to another heavily n-doped region separation distance d₁ₚ_{_{—}}ₚ exceeds twice the difference between the depth of the intra-well trench isolation structure 6 and the depth of the heavily n-doped region 91, and consequently exceeds 400 nm. The intra-well trench minimum width w2_p may be limited not by intra-well device isolation considerations, but by process capability considerations to insure filling of the intra-well trench isolation structures 6 with a dielectric material. Considerations on the prior art heavily p-doped region to another heavily p-doped region separation distance d₁ₙ_{_{—}}ₚ produces the same result.

Therefore, the inter-well trench minimum width w1_p of the inter-well trench isolation structure 4 may be a limiting factor on device density in the design of CMOS circuits. This is a severe limitation since most CMOS circuits require placement of p-type devices and n-type devices in close proximity, thus consuming a substantial area for the inter-well trench isolation structures. A reduced minimum dimension for the width of intra-well trench isolation structures would enable design of CMOS circuits having a higher device density.

Therefore, there exists a need for an inter-well trench isolation structure that provides electrical isolation between adjacent wells having different doping types and having reduced minimum width compared to the prior art and methods of manufacturing the same.

In particular, there exists a need for such an inter-well trench isolation structure that requires minimal additional processing steps in terms of cost and complexity during the manufacturing.

### SUMMARY OF THE INVENTION

The present invention addresses the needs described above by providing an inter-well trench isolation structure having an extended portion that protrudes deeper into a semiconductor substrate than normal trench isolation structures.

Specifically, at least one pad layer is lithographically patterned so that an opening is formed in an inter-well isolation area, which has a width greater than that of at least one intra-well isolation area. A semiconductor material layer or a dielectric material layer is deposited over the openings in the at least one pad layer. After a first stage of a reactive ion etch, the openings in the at least one intra-well isolation area is plugged by the semiconductor material layer or the dielectric material layer, while a spacer is formed around the walls of the at least one pad layer on the periphery of the opening within the inter-well isolation area. After a second stage of reactive ion etch, the remainder of the semiconductor material layer or the dielectric material layer and the semiconductor substrate material underneath are removed to form an inter-well isolation trench having an extended portion.

As the reactive ion etch proceeds further, at least one narrow intra-well isolation trench is formed with a normal depth in the at least one intra-well isolation area, while a wider inter-well isolation trench with an extended portion below the normal depth is formed in the inter-well isolation area. The extended portion of the wider trench in the inter-well isolation area increases the distance between the different semiconductor regions having the same type of doping, thus providing enhanced electrical isolation among them. Thus, the extended portion of the inter-well isolation trench enables reduction of the width of inter-well trench isolation structures relative to prior art inter-well isolation structures having a normal depth.

According to one aspect of the present invention, a semiconductor structure comprises:
a. a semiconductor substrate having a top surface;
b. a p-well located in the semiconductor substrate;
c. an n-well located in the semiconductor substrate and abutting the p-well;
d. a pair of substantially vertical first trench sidewalls abutting one of the p-well and the n-well and extending from the top surface to a first depth;
e. a pair of substantially horizontal first trench bottom surfaces located at the first depth and abutting one of the p-well and the n-well and adjoined to one of the substantially vertical first trench sidewalls;
f. a pair of substantially vertical second trench sidewalls abutting one of the p-well and the n-well and extending from one of the substantially horizontal first trench bottom surfaces to a second depth;
g. a substantially horizontal second trench bottom surface located at the second depth and abutting both the p-well and the n-well and adjoined to the pair of substantially vertical second trench sidewalls; and
h. a trench isolation structure bounded by the pair of substantially vertical first trench sidewalls, the pair of substantially horizontal first trench bottom surfaces, the pair of substantially vertical second trench sidewalls, and the substantially horizontal second trench bottom surface and comprising an insulator material.

Each of the p-well and the n-well has a dopant concentration in the range from about 5.0×10¹⁶ atoms/cm³ to about 5.0×10¹⁹ atoms/cm³.

The semiconductor structure may further comprise:
a. at least one heavily n-doped region abutting the p-well, the top surface, and one of the pair of substantially vertical first trench sidewalls; and
b. at least one heavily p-doped region abutting the n-well, the top surface, and the other of the pair of the substantially vertical first trench sidewalls, wherein each of the at least one heavily n-doped region and the at least one heavily p-doped region has a dopant concentration in the range from about 5.0×10¹⁹ atoms/cm³ to about 5.0×10²¹ atoms/cm³.

According to another aspect of the present invention, a method of forming a semiconductor structure comprises:
a. forming at least one pad layer on a top surface of a semiconductor substrate;
b. lithographically patterning and etching the stack of pad layers within an inter-well isolation area;
c. depositing a substantially conformal layer having a pair of inner sidewalls within the inter-well isolation area;
d. forming a trench having a flat bottom surface and a width that is substantially the same as the distance between sad pair of inner sidewalls within the semiconductor substrate;
e. expanding the trench to form a trench containing a pair of substantially vertical first trench sidewalls extending from the top surface to a first depth, a pair of substantially horizontal first trench bottom surfaces located at the first depth and adjoined to one of the substantially vertical first trench sidewalls, a pair of substantially vertical second trench sidewalls and extending from one of the substantially horizontal first trench bottom surfaces to a second depth, and a substantially horizontal second trench bottom surface located at the second depth and adjoined to the pair of substantially vertical second trench sidewalls.

The method may further comprise:
a. forming a p-well in the semiconductor substrate, wherein the p-well abuts the substantially horizontal second trench bottom surface; and
b. forming an n-well in the semiconductor substrate, wherein the n-well abuts the p-well and the substantially horizontal second trench bottom surface.

The method may further comprise:
a. forming a heavily n-doped region abutting one of the pair of substantially vertical first trench sidewalls on the p-well; and
b. forming a heavily p-doped region abutting the other of the pair of substantially vertical first trench sidewalls on the n-well.

### BRIEF DESCRIPTION OF THE DRAWINGS

FIG. 1 is a vertical cross-sectional view of a prior art trench isolation structure.

FIGS. 2-13 show sequential vertical cross-sectional views of a first exemplary semiconductor structure according to a first embodiment of the present invention at various stages of a manufacturing sequence.

FIGS. 14-17 show sequential vertical cross-sectional views of a second exemplary semiconductor structure according to a second embodiment of the present invention at selected stages of a manufacturing sequence.

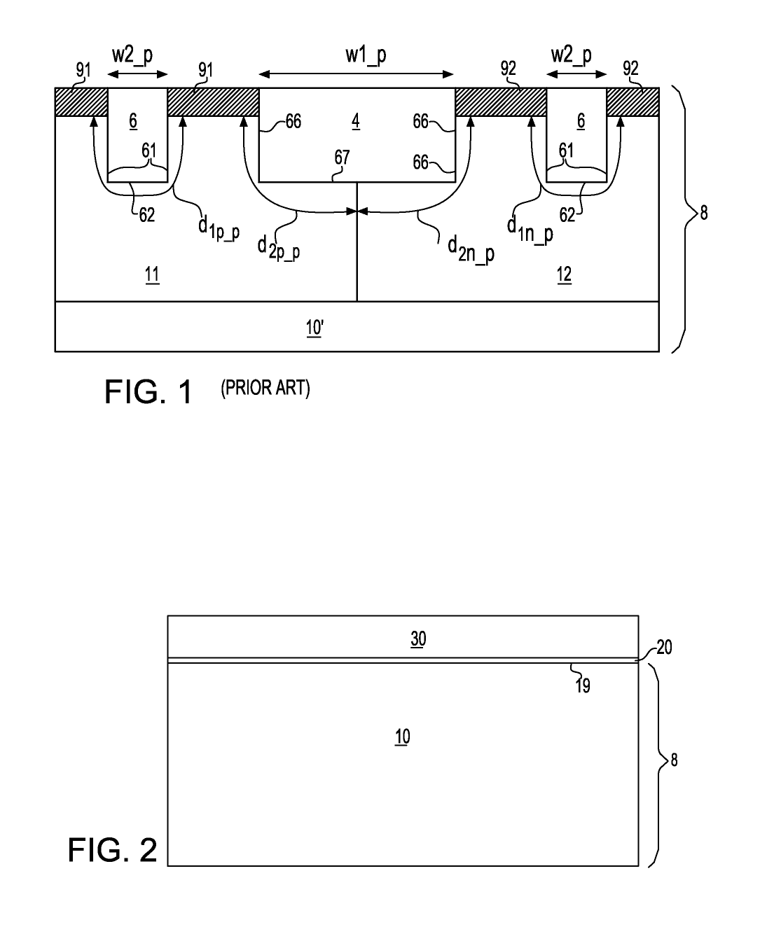

### DETAILED DESCRIPTION OF THE INVENTION

As stated above, the present invention relates to an intra-well isolation structure with an extended depth and methods of manufacturing the same, which are now described in detail with accompanying figures. It is noted that like and corresponding elements are referred to by like reference numerals.

Referring to FIG. 2, a first exemplary semiconductor structure comprises a semiconductor substrate 8 having a top surface 19 and at least one pad layer formed thereupon. At this point, the semiconductor substrate 8 comprises entirely of an original substrate layer 10 having an original doping concentration as provided. The original substrate layer 10 may comprise silicon, silicon-carbon alloy, silicon germanium alloy, silicon-carbon-germanium alloy, GaAs, InAs, InP, other III-V compound semiconductors, or II-VI compound semiconductors. The at least one pad layer may comprise a stack of a first pad layer 20 and a second pad layer 30.

The original substrate layer 10 may be p-doped or n-doped, i.e., may have more of p-type dopants than n-type dopants or vice versa. Preferably, the original substrate layer 10 has a dopant concentration in the range from about 1.0×10¹⁵ atoms/cm³ to about 1.0×10¹⁸ atoms/cm³.

The material for the first pad layer 20 is typically chosen to enhance adhesion between the original substrate layer 10 and the second pad layer 30. Preferably, the material for the second pad layer 30 may be etched selective to the material of the original substrate layer 10 in a reactive ion etch. The thickness of the first pad layer 20 may be in the range from about 5 nm to about 50 nm, and is typically about 20 nm. The thickness of the second pad layer may be in the range from about 20 nm to about 400 nm, and preferably in the range from about 60 nm to about 150 nm. For example, the original substrate layer 10 may comprise silicon, the first pad layer 20 may comprise silicon oxide, and the second pad layer 30 may comprise silicon nitride.

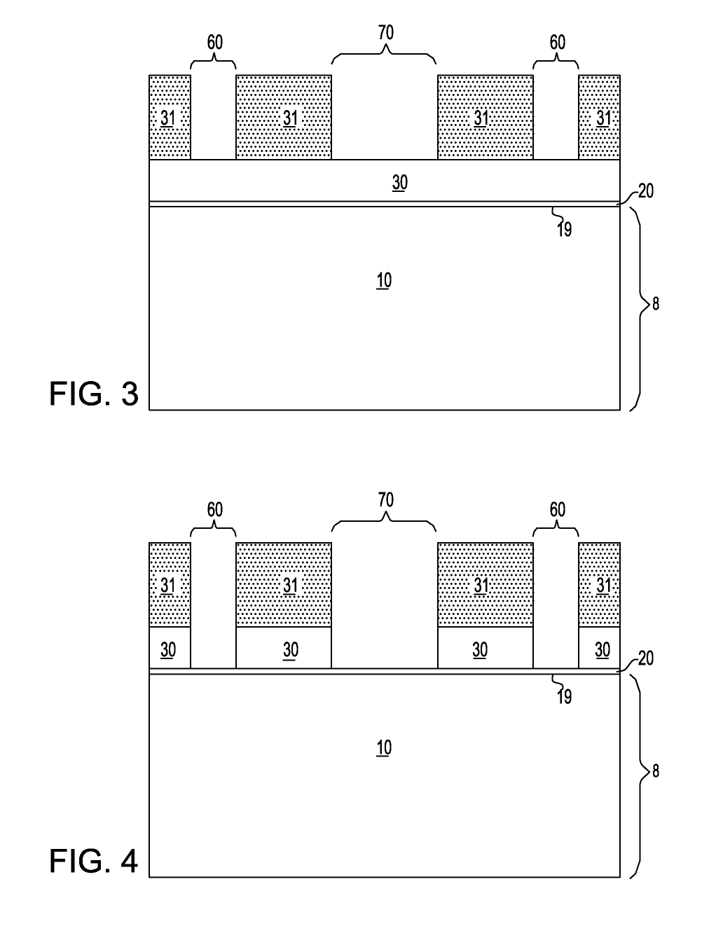

Referring to FIG. 3, a photoresist 31 is applied to the at least one pad layer (20, 30) and lithographically patterned. Specifically, the photoresist 31 is applied to the second pad layer 30 and lithographically patterned for an inter-well isolation area 70 and, preferably, at least one intra-well isolation area 60. The width of the inter-well isolation area 70 is greater than the width of the at least one intra-well isolation area 60. Typically, the width of the at least one intra-well isolation area 60 is determined by lithographic limitations or by limitations of trench fill processes to be subsequently performed. In other words, the width of the intra-well isolation area 60 may be as small as a critical dimension of a lithography tool that is used to form the intra-well isolation area 60, and it is large enough to allow a dielectric material deposited in the trench fill process to fill a trench formed in the intra-well isolation area 60.

Referring to FIG. 4, the pattern in the photoresist 31 is transferred into the at least one pad layer (20, 30) by a reactive ion etch. Specifically, the exposed portions of the second pad layer 30 in the inter-well isolation area 70 and, preferably, the at least one intra-well isolation area 60 are etched in a reactive ion etch employing the patterned photoresist 31 as an etch mask. The second pad layer 30 is etched through down to the first pad layer 30.

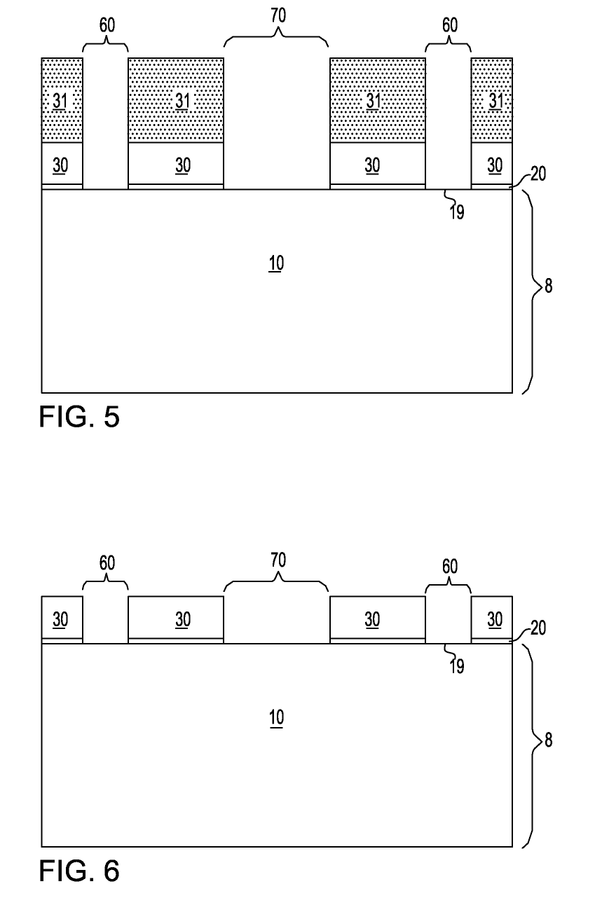

Referring to FIG. 5, the pattern in the photoresist 31 is further transferred into the first pad layer 20. This transfer may be performed by another reactive ion etch or by a wet etch. The sop surface 19 of the semiconductor substrate 8 is exposed in the inter-well isolation area 70 and, preferably, the at least one intra-well isolation area 60.

Referring to FIG. 6, the photoresist 31 is removed, for example, by ashing. The surfaces of the remaining semiconductor structure may be cleaned, for example, by a wet clean as needed.

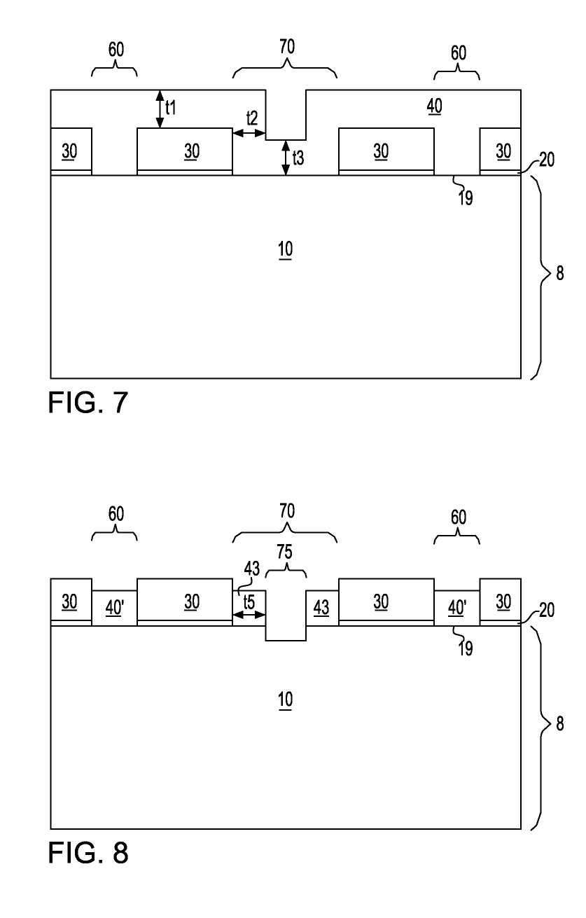

Referring to FIG. 7, a semiconductor material layer 40 is deposited on the exposed surface of the original substrate layer 10, the sidewalls of the patterned pad layers (20, 30), and on top surfaces of the second pad layer 30. The semiconductor material layer 40 has a pair of inner sidewalls within the inter-well isolation area 70. Preferably, the semiconductor material layer 40 is substantially conformal, that is, a first thickness t1 of the semiconductor material layer over the second pad layer 30, a second thickness t2 of the semiconductor material layer 40 as measured at the inner sidewalls, and the third thickness t3 of the semiconductor material layer on the substrate layer 10 within the inter-well isolation area 70 are substantially the same, i.e., t1≅t2≅t3. The second thickness t2 is also the horizontal distance between an inner sidewall of the semiconductor material layer 40 and the nearest sidewall of the at least one pad layer (20, 30).

As noted above, the width of the inter-well isolation area 70 is greater than the width of the at least one intra-well isolation area 60. The second thickness t2 of the semiconductor material layer 40 is selected such that twice the second thickness t2 is less than the width of the inter-well isolation area 70 and is greater than the width of the at least one intra-well isolation area 60. Therefore, a recessed region is formed between inner sidewalls of the semiconductor material layer 40 within the inter-well isolation area 70, while the opening(s) in the at least one intra-well isolation area 60 is/are plugged by the semiconductor material layer 40. Typically, the second thickness t2 may be in the range from about 10 nm to about 200 nm, preferably in the range from about 20 nm to about 80 nm. The width of the inter-well isolation area 70 may be in the range from about 30 nm to about 600 nm, preferably in the range from about 40 nm to about 220 nm. The width of the at least one intra-well isolation area 60 may be in the range from about 15 nm to about 390 nm, preferably in the range from about 30 nm to about 150 nm.

The semiconductor material layer 40 comprises a semiconductor material such as silicon, silicon-carbon alloy, silicon germanium alloy, silicon-carbon-germanium alloy, GaAs, InAs, InP, other III-V compound semiconductors, and II-VI compound semiconductors. Preferably, the semiconductor material layer 40 comprises substantially the same material as the original substrate layer 10. For example, if the original substrate layer 10 comprises crystalline silicon, the semiconductor material layer 40 may comprise amorphous silicon, amorphous silicon-containing alloy, polysilicon, or polycrystalline silicon containing alloy. The original substrate layer 10 and the semiconductor material layer 40 may have the same, or different, type of doping.

Referring to FIG. 8, the semiconductor material layer 40 is etched by a reactive ion etch that is selective to the second pad layer 30. After a first stage of the reactive ion etch process, a semiconductor material spacer 43 is formed in the inter-well isolation area 70, and at least one thinned semiconductor material plug 40′ is formed in the at least one intra-well isolation area 60. Also, as the semiconductor material layer 40 is removed from above the semiconductor layer 40 and the semiconductor material spacer 43 is formed on the sidewalls of the at least one pad layer (20, 30), an inner trench 75 is formed within the original substrate layer 10 between the two portions of the semiconductor material spacer 43.

During the second stage of the reactive ion etch process, both the semiconductor material spacer 43 and the at least one thinned semiconductor material plug 40′ continue to be etched until they disappear. As more material is etched from the original substrate layer 10, the inner trench 75 becomes deeper. As the reactive ion etch proceeds further after semiconductor material spacer 43 and the at least one thinned semiconductor material plug 40′ are completely etched, more material is removed from the original substrate layer 10 and an inter-well isolation trench containing the inner trench 75 is etched deeper into the semiconductor substrate 8 in the inter-well isolation area 70. At the same time, at least one intra-well isolation trench is also etched deeper into the semiconductor substrate 8 in the at least one intra-well isolation area 60. The reactive ion etch process expands the volume of the inter-well isolation trench and at least one intra-well isolation trench.

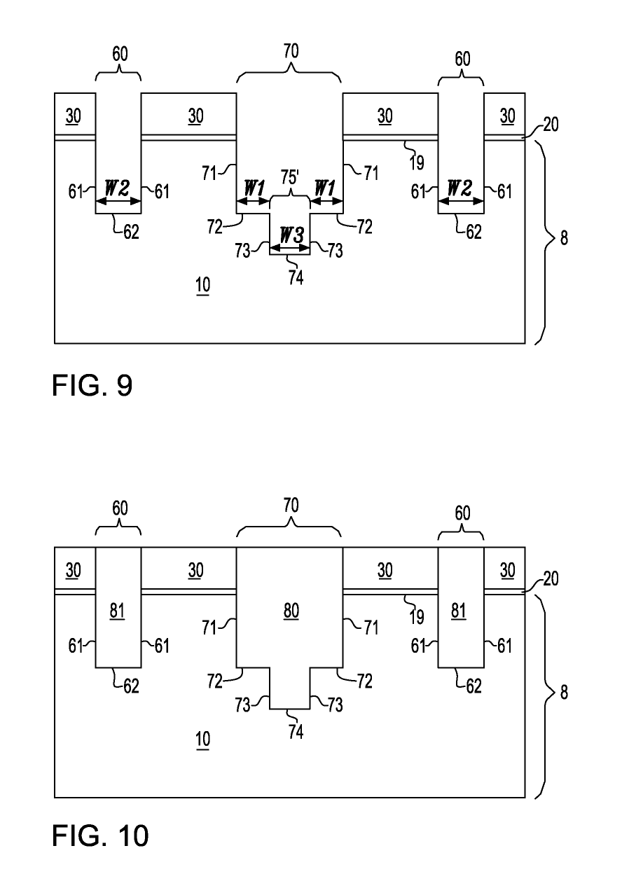

Referring to FIG. 9, an inter-well isolation trench containing an extended trench 75′ is formed in the inter-well isolation area 70 by the end of the reactive ion etch process. The extended trench 75′ is formed by a transfer of the recessed feature of the inner trench 75 into the original substrate layer 10 during the reactive ion etch process. Further, at least one intra-well isolation trench is formed in the at least one intra-well isolation area 60. The inter-well isolation trench comprises a pair of substantially vertical first trench sidewalls 71 extending from the top surface 19 to a first depth, a pair of substantially horizontal first trench bottom surfaces 72 located at the first depth and adjoined to one of the substantially vertical first trench sidewalls 71, a pair of substantially vertical second trench sidewalls 73 extending from one of the substantially horizontal first trench bottom surfaces 72 to a second depth, and a substantially horizontal second trench bottom surface 74 located at the second depth and adjoined to the pair of substantially vertical second trench sidewalls 73. The extended trench 75′ has an “extended depth” since the pair of substantially vertical second trench sidewalls 73 and the substantially horizontal second trench bottom surface 74 extend below the first depth, or the normal depth of isolation trenches such as the at least one intra-well isolation trench. In other words, the extended trench 75′ is located beneath the first depth, which is the depth of other normal isolation trenches.

Each of the pair of substantially horizontal first trench bottom surfaces 72 has substantially the same first width W1, which is substantially the same as the second thickness t2 of the semiconductor material layer 40. The first width W1 may be in the range from about 10 nm to about 200 nm. The width W3 of the substantially horizontal second trench bottom surface 74 is greater than the overlay tolerance of block masks to be used during well implantations in subsequent processing steps. The width W3 may, or may not be sublithographic.

Further, each of the at least one intra-well isolation trench has a pair of substantially vertical third trench sidewalls 61 and a substantially horizontal third trench bottom surface 62 located at a depth that is substantially the same as the first depth from the top surface 19 of the semiconductor substrate 8. The at least one intra-well isolation trench has a second width W2 in the range from about 20 nm to about 400 nm. The second width W2 is typically less than twice the first width W1.

The height of the pair of substantially vertical second trench sidewalls 73 may be substantially the same as the thickness of the at least one pad layer (20, 30), or the combined thickness of the first pad layer 20 and the second pad layer 30. The combined thickness may be in the range from about 20 nm to about 400 nm. Consequently, the height of the pair of substantially vertical second trench sidewalls 73 may be in the range from about 20 nm to about 400 nm.

The various trench sidewalls (71, 73, 61) are substantially vertical, i.e., have an angle relative to the top surface 19 of the semiconductor substrate in the range from about 80 degrees to about 100 degrees, and preferably in the range from about 85 degrees to about 95 degrees.

The various trench bottom surfaces (72, 74, 62) are substantially horizontal, i.e., have an angle relative to the top surface 19 of the semiconductor substrate in the range from about −10 degrees to about 10 degrees, and preferably in the range from about −5 degrees to about 5 degrees.

Referring to FIG. 10, a dielectric material is deposited within the inter-well isolation trench to form an inter-well trench isolation structure 80 and within the at least one intra-well isolation trench to form at least one intra-well isolation trench structure 81. The dielectric material may comprise an oxide, a nitride, an oxynitride, or a stack thereof. The dielectric material preferably comprises an oxide such as silicon dioxide.

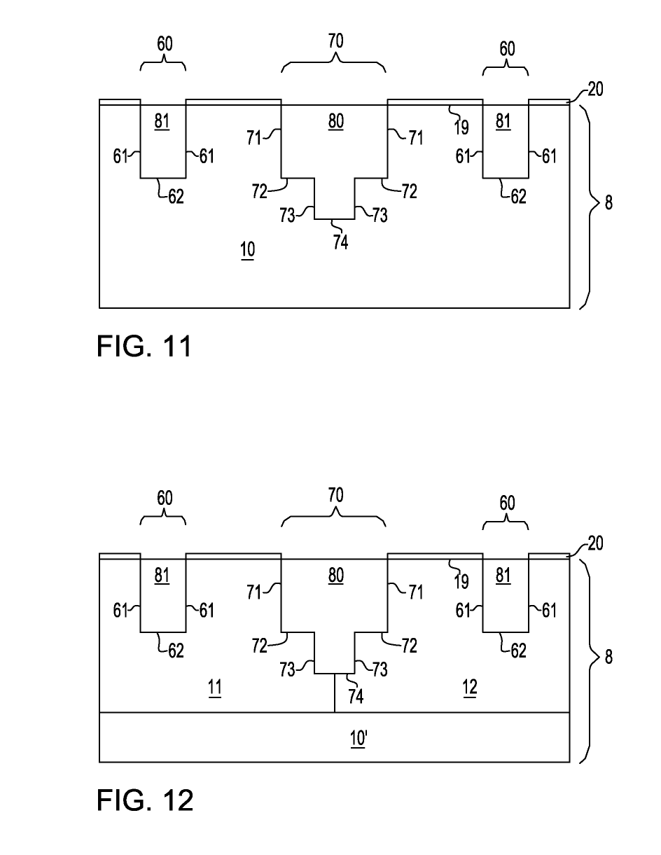

Referring to FIG. 11, the second pad layer 30 is removed from above the first pad layer 20. A wet etch may be employed to remove the second pad layer 30 without affecting the remaining structural elements on the semiconductor substrate 8.

Referring to FIG. 12, by employing block masks (not shown) and ion implantation, a p-well 11 is formed within a portion of the original substrate layer 10 and an n-well 11 is formed within another portion of the original substrate layer. Specifically, a first block mask is applied over the semiconductor substrate 8 and patterned such that the patterned first block mask covers the complementary area of the area in which the p-well 11 is to be formed. A p-well ion implantation is performed to implant p-type dopants into the exposed portion of the semiconductor substrate 8, thus forming the p-well 11. The first block mask is removed and a second block mask is thereafter applied over the semiconductor substrate 8 and patterned such that the patterned second block mask covers the complementary area of the area in which the n-well 12 is to be formed. An n-well ion implantation is performed to implant n-type dopants into the exposed portion of the semiconductor substrate 8, thus forming the n-well 12. Each of the p-well 11 and the n-well 12 has a dopant concentration in the range from about 50×10¹⁶ atoms/cm³ to about 5.0×10¹⁹ atoms/cm³.

The border between the p-well 11 and the n-well 12 adjoins the substantially horizontal second trench bottom surface 74. The portion of the original substrate layer 10 that is not implanted with dopant ions during either the p-well ion implantation or the n-well ion implantation forms a substrate layer 10′, which abuts both the p-well 11 and the n-well 12. The depths of the p-well 11 and the n-well 12, as measured from the top surface 19 of the semiconductor substrate 8 to the bottom surfaces of the p-well 11 and the n-well 12, may be the same or different, and are typically in the range from about 200 nm to about 1,800 nm.

The surfaces of the inter-well isolation structure 80 abut at least one of the p-well 11 and the n-well 12. Specifically, each of the pair of substantially vertical first trench sidewalls 71 abuts one of the p-well 11 and the n-well 12, each of the pair of substantially horizontal first trench bottom surfaces 72 abuts one of the p-well 11 and the n-well 12, each of the pair of substantially vertical second trench sidewalls 73 abuts one of the p-well 11 and the n-well 12, and the substantially horizontal second trench bottom surface 74 abuts both the p-well 11 and the n-well 12. The set of surfaces of each of the at least one intra-well isolation structure abuts either the p-well 11 or the n-well 12.

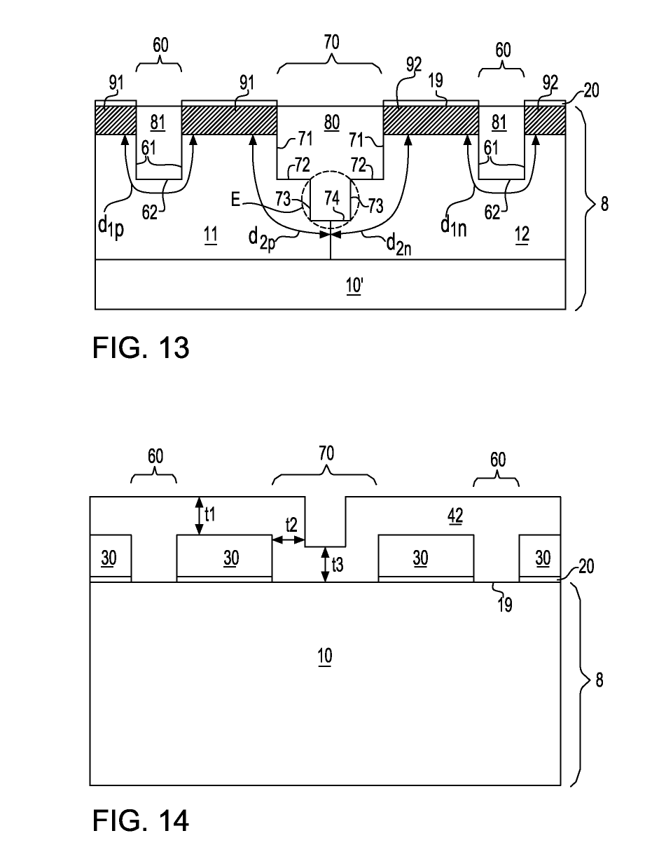

Referring to FIG. 13, a heavily n-doped region 91 and a heavily p-doped region 92 are formed by block masks (not shown) and ion implantation in a manner similar to the formation of the p-well 11 and the n-well. The heavily n-doped region 91 and the heavily p-doped region abut the top surface 19 of the semiconductor substrate 8 and may abut the pair of substantially vertical first trench sidewalls 71. Each of the at least one heavily n-doped region 91 and the at least one heavily p-doped region 92 has a dopant concentration in the range from about 5.0×10¹⁹ atoms/cm³ to about 5.0×10²¹ atoms/cm³. The extended portion E of the inter-well isolation trench 70 comprises a dielectric material bounded by the pair of substantially vertical second trench sidewalls 73 and the substantially horizontal second trench bottom surface 74.

The path of the weakest intra-p-well isolation in the first exemplary isolation structure is represented by a heavily n-doped region to another heavily n-doped region separation distance d₁ₚ. The path of the weakest intra-n-well isolation in the first exemplary isolation structure is represented by a heavily p-doped region to another heavily p-doped region separation distance d₁ₙ. For identical dimensions in the at least one intra-well isolation structure 81, both the prior art and the present invention result in the same heavily n-doped region to another heavily n-doped region separation distance d₁ₚ and heavily p-doped region to another heavily p-doped region separation distance d₁ₙ.

The present invention increases the paths of the weakest inter-well isolation for comparable widths of an inter-well isolation area relative to the prior art structure described above. The paths of the weakest inter-well isolation in the first exemplary isolation structure are represented by a heavily n-doped region to n-well separation distance d₂ₚ and a heavily p-doped region to p-well separation distance d₂ₙ, each of which is extended by the height of the extended portion E of the inter-well isolation trench structure 80 compared to the prior art structure, which do not have such an extended portion E. The height of the extended portion E is the height of the pair of the substantially vertical second trench sidewalls 73, which is in the range from about 20 nm to about 400 nm. Compared to the prior art, the increase in the separation distances d₂ₚ and d₂ₙ enables reduction of the width of the inter-well isolation area 70 and consequent increase in the density of semiconductor devices on a semiconductor chip.

For example, the depths of the at least one heavily n-doped region 91 and the at least one heavily p-doped region 92 may be about 80 nm, and the first depth, which is the depth of the pair of substantially horizontal first trench bottom surfaces 72 and the at least one substantially horizontal third trench bottom surface 62, may be about 280 nm. The height of the pair of substantially vertical second trench sidewalls 73 may be about 80 nm. Since both the heavily n-doped region to n-well separation distance d₂ₚ and a heavily p-doped region to p-well separation distance d₂ₙ are increased by the height of the pair of substantially vertical second trench sidewalls 73, the minimum width of the inter-well isolation region 70 may be reduced by 160 nm, i.e., the width of the inter-well isolation region may be only 120 nm according to the present invention. Such reduction in the minimum width of the inter-well isolation area enables design of CMOS circuits with higher device density.

Referring to FIG. 14, a second exemplary isolation structure according to the present invention is shown during a step in a manufacturing process. The second exemplary structure in FIG. 14 is obtained by depositing a dielectric material layer 42 to the first exemplary structure shown in FIG. 6. Specifically, the dielectric material layer 42 is deposited on the exposed surface of the original substrate layer 10, the sidewalls of the patterned pad layers (20, 30), and on top surfaces of the second pad layer 30. The dielectric material layer 42 has a pair of inner sidewalls within the inter-well isolation area 70. Preferably, the dielectric material layer 42 is substantially conformal, that is, a first thickness t1 of the dielectric material layer 42 over the second pad layer 30, a second thickness t2 of the dielectric material layer 42 as measured at the inner sidewalls, and the third thickness t3 of the dielectric material layer 42 on the substrate layer 10 within the inter-well isolation area 70 are substantially the same, i.e., t1≅t2≅t3.

The width of the at least one intra-well isolation area 60 is less than twice the second thickness t2. Specifications for the second thickness t2, for the width of the at least one intra-well isolation area 60, and for the width of the inter-well isolation area 70 are the same as in the first embodiment of the present invention. A recessed region is formed between inner sidewalls of the dielectric material layer 42 within the inter-well isolation area 70, while the opening(s) in the at least one intra-well isolation area 60 is/are plugged by the dielectric material layer 42. The dielectric material layer 42 comprises a dielectric material such as an oxide, a nitride, an oxynitride, or a stack thereof. Preferably, the dielectric material layer 42 comprises a different material than the second pad layer 30. For example, the second pad layer 30 may comprise silicon nitride and the dielectric material layer 42 may comprise silicon oxide.

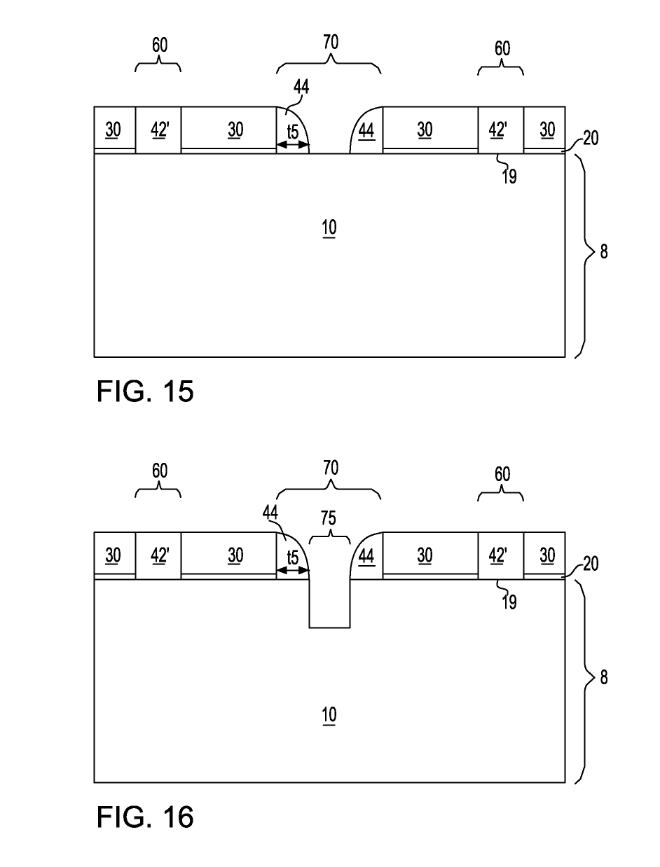

Referring to FIG. 15, the dielectric material layer 42 is etched by a first reactive ion etch. The first reactive ion etch may be selective to the semiconductor material in the original substrate layer 10. During the reactive ion etch process, a dielectric material spacer 44 is formed in the inter-well isolation area 70, and at least one dielectric material plug 42′ is formed in the at least one intra-well isolation area 60. The top surface 19 of the semiconductor substrate 8 is exposed in the area surrounded by the dielectric material spacer 44.

Referring to FIG. 16, semiconductor material is etched by a second reactive ion etch from the exposed portion of the original substrate layer 10. The second reactive ion etch is preferably selective to the second pad layer 30 and to the dielectric material spacer 44. As the semiconductor material is removed from the original substrate layer 10, an inner trench 75 is formed within the original substrate layer 10 between the semiconductor material spacer 43.

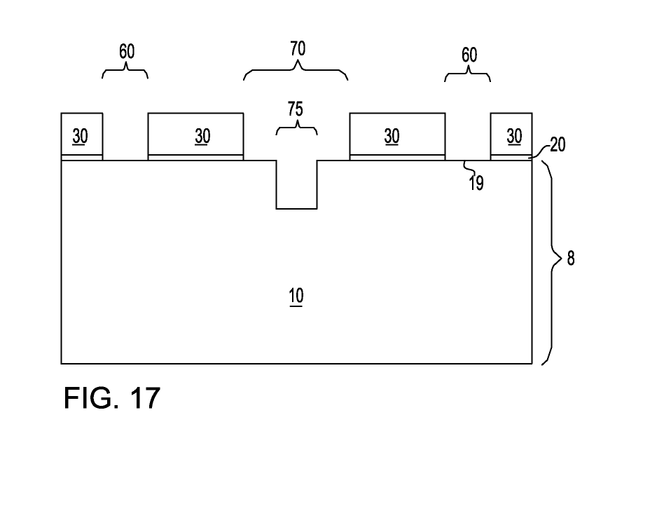

Referring to FIG. 17, the dielectric material spacer 44 is removed selective to the second pad layer 30 and the original substrate layer 10. For example, if the second pad layer 40 comprises silicon nitride and the dielectric material spacer 44 comprises silicon oxide, a hydrofluoric acid (HF) based wet etch may be employed to selectively remove the dielectric material spacer 44. A reactive ion etch of the semiconductor material in the original substrate layer 10 is performed thereafter to produce the same structure as described in FIG. 9 according to the first embodiment of the present invention. The same process sequence may be employed to form the same intra-well isolation structure as described in the first embodiment of the present invention.

While the invention has been described in terms of specific embodiments, it is evident in view of the foregoing description that numerous alternatives, modifications and variations will be apparent to those skilled in the art. Accordingly, the invention is intended to encompass all such alternatives, modifications and variations which fall within the scope and spirit of the invention and the following claims.

What is claimed is:

1. A semiconductor structure comprising:
a semiconductor substrate having a top surface;
a p-well located in said semiconductor substrate;
an n-well located in said semiconductor substrate and abutting said p-well;
a pair of substantially vertical first trench sidewalls abutting one of said p-well and said n-well and extending from said top surface to a first depth;
a pair of substantially horizontal first trench bottom surfaces located at said first depth and abutting one of said p-well and said n-well and adjoined to one of said substantially vertical first trench sidewalls;
a pair of substantially vertical second trench sidewalls abutting one of said p-well and said n-well and extending from one of said substantially horizontal first trench bottom surfaces to a second depth;
a substantially horizontal second trench bottom surface located at said second depth and abutting both said p-well and said n-well and adjoined to said pair of substantially vertical second trench sidewalls; and
a trench isolation structure bounded by said pair of substantially vertical first trench sidewalls, said pair of substantially horizontal first trench bottom surfaces, said pair of substantially vertical second trench sidewalls, and said substantially horizontal second trench bottom surface and comprising an insulator material.

2. The semiconductor structure of claim 1, wherein each of said p-well and said n-well has a dopant concentration in the range from about 5.0×10¹⁶ atoms/cm³ to about 5.0×10¹⁹ atoms/cm³.

3. The semiconductor structure of claim 1, further comprising:
at least one heavily n-doped region abutting said p-well, said top surface, and one of said pair of substantially vertical first trench sidewalls; and
at least one heavily p-doped region abutting said n-well, said top surface, and the other of said pair of substantially vertical first trench sidewalls, wherein each of said at least one heavily n-doped region and said at least one heavily p-doped region has a dopant concentration in the range from about 5.0×10¹⁹ atoms/cm³ to about 5.0×10²¹ atoms/cm³.

4. The semiconductor structure of claim 1, further comprising a substrate layer having a dopant concentration in the range from about 1.0×10¹⁵ atoms/cm³ to about 1.0×10¹⁸ atoms/cm³ and located directly beneath said p-well and said n-well.

5. The semiconductor structure of claim 1, wherein said pair of substantially vertical second trench sidewalls has a height in the range from about 20 nm to about 400 nm.

6. The semiconductor structure of claim 1, wherein said insulator material comprises an oxide.

7. The semiconductor structure of claim 1, wherein each of said pair of substantially horizontal first trench bottom surfaces has substantially the same first width.

8. The semiconductor structure of claim 7, wherein said first width is in the range from about 10 nm to about 200 nm.

9. The semiconductor structure of claim 8, further comprising at least one intra-well isolation structure having a second width in the range from about 20 nm to about 400 nm and a depth that is substantially the same as said first depth.

10. The semiconductor structure of claim 9, wherein said second width is less than twice said first width.

11. A method of forming a semiconductor structure comprising:
forming at least one pad layer on a top surface of a semiconductor substrate;
lithographically patterning and etching said at least one pad layer in an inter-well isolation area;
depositing a substantially conformal layer having a pair of inner sidewalls within said inter-well isolation area;
forming an inner trench having a flat bottom surface and a width that is substantially the same as the distance between sad pair of inner sidewalls within said semiconductor substrate; and
forming a trench containing a pair of substantially vertical first trench sidewalls extending from said top surface to a first depth, a pair of substantially horizontal first trench bottom surfaces located at said first depth and adjoined to one of said substantially vertical first trench sidewalls, a pair of substantially vertical second trench sidewalls and extending from one of said substantially horizontal first trench bottom surfaces to a second depth, and a substantially horizontal second trench bottom surface located at said second depth and adjoined to said pair of substantially vertical second trench sidewalls.

12. The method of claim 11, wherein said pair of substantially vertical first trench sidewalls is substantially coincident with a periphery of said inter-well isolation area and said pair of substantially vertical second trench sidewalls and said substantially horizontal second trench bottom surface are formed by etching of the material of said semiconductor substrate beneath said inner trench.

13. The method of claim 11, further comprising:
forming a p-well in said semiconductor substrate, wherein said p-well abuts said substantially horizontal second trench bottom surface; and
forming an n-well in said semiconductor substrate, wherein said n-well abuts said p-well and said substantially horizontal second trench bottom surface.

14. The method of claim 13, further comprising:
forming a heavily n-doped region abutting one of said pair of substantially vertical first trench sidewalls on said p-well; and
forming a heavily p-doped region abutting the other of said pair of substantially vertical first trench sidewalls on said n-well.

15. The method of claim 11, further comprising filling said trench with a dielectric material.

16. The method of claim 11, wherein each of said pair of substantially horizontal first trench bottom surfaces has substantially the same first width.

17. The method of claim 16, further comprising forming at least one intra-well isolation structure having a second width in the range from about 20 nm to about 400 nm and a depth that is substantially the same as said first depth.

18. The method of claim 11, wherein said substantially conformal layer is a semiconductor material layer comprising a material selected from the group consisting of silicon, silicon-carbon alloy, silicon germanium alloy, silicon-carbon-germanium alloy, GaAs, InAs, InP, other III-V compound semiconductors, and II-VI compound semiconductors.

19. The method of claim 11, wherein said substantially conformal layer is a dielectric material layer comprising a material selected from the group consisting of an oxide, a nitride, an oxynitride, and a stack thereof.

20. The method of claim 19, further comprising forming a spacer out of said dielectric material layer on said at least one pad layer in said inter-well isolation area.
